(19) United States
(12) Patent Application Publication
(10) Pub. No.: US 2012/0067721 A1
(43) Pub. Date: Mar. 22, 2012

(54) TARGET ASSEMBLY

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); SHUN-MAO LIN, Shenzhen (CN)

(73) Assignees: HON HAI PRECISION INDUSTRY CO., LTD., TU-CHENG (TW); HONG FU JIN PRECISION INDUSTRY (SHENZHEN) CO., LTD., SHENZHEN CITY (CN)

(21) Appl. No.: 13/084,646

(22) Filed: Apr. 12, 2011

(30) Foreign Application Priority Data
Sep. 21, 2010 (CN) 201010289175.0

(51) Int. Cl. C23C 14/14; C23C 14/34

(52) U.S. Cl. 204/298.13; 204/298.12

(57) ABSTRACT

A target assembly includes a base comprising a first surface and a second surface opposite to the first surface. The base defining a threaded hole; a magnetron mounted on a first surface; a target movably mounted to the second surface, the target defining an opening corresponding to the threaded hole, the opening including a first end and a second end; and a screw. The screw can slide in the opening from the first end to the second end so the position between magnetron and the target is adjusted to adjust the bombarded area of the target.

### BACKGROUND

1. Technical Field

The exemplary disclosure generally relates to target assemblies used in magnetron sputtering process.

2. Description of Related Art

Magnetron sputtering is a process whereby atoms are ejected from a solid target due to a bombardment of the target by energetic particles of a magnetron. It is commonly used for thin-film deposition, etching and analytical techniques. Typically, the position between the target and the magnetron cannot be adjusted so the bombarded area of the target cannot be adjusted, and the utilization rate of the target is low.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary target assembly. Moreover, in the drawings like reference numerals designate corresponding parts throughout the several views. Wherever possible, the same reference numbers are used throughout the drawings to refer to the same or like elements of an embodiment.

FIG. 1 is a cross-section of an exemplary embodiment of target assembly in a first position.

FIG. 2 is a plane view of the target assembly of FIG. 1.

FIG. 3 is a cross-section of the target assembly of FIG. 1 in a second position.

FIG. 4 is a plane view of the target assembly of FIG. 3.

FIG. 5 is a cross-section of the target assembly of FIG. 1 in a third position.

FIG. 6 is a cross-section of another exemplary embodiment of target assembly in a first position.

FIG. 7 is a cross-section of the target assembly of FIG. 6 in a second position.

### DETAILED DESCRIPTION

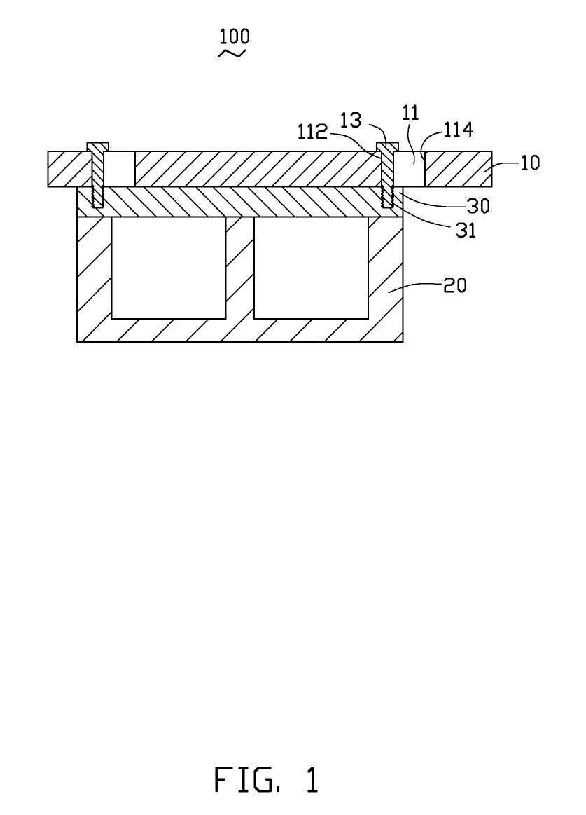

Referring to FIG. 1, an exemplary embodiment of a target assembly 100 used in magnetron sputtering process is shown. The target assembly 100 includes a target 10, a magnetron 20, a base 30 and a plurality of screws 13. The magnetron 20 is mounted on a first surface of the base 30, the target 10 is adjustably positionable relative to a second surface of the base 30 opposite to the magnetron 20 by the screws 13. The base 30 is made of magnetic material so the magnetron 20 can be attached to the base 30 by the magnetic force. The target 10 is made of metal, alloy, metal oxide or metal nitride.

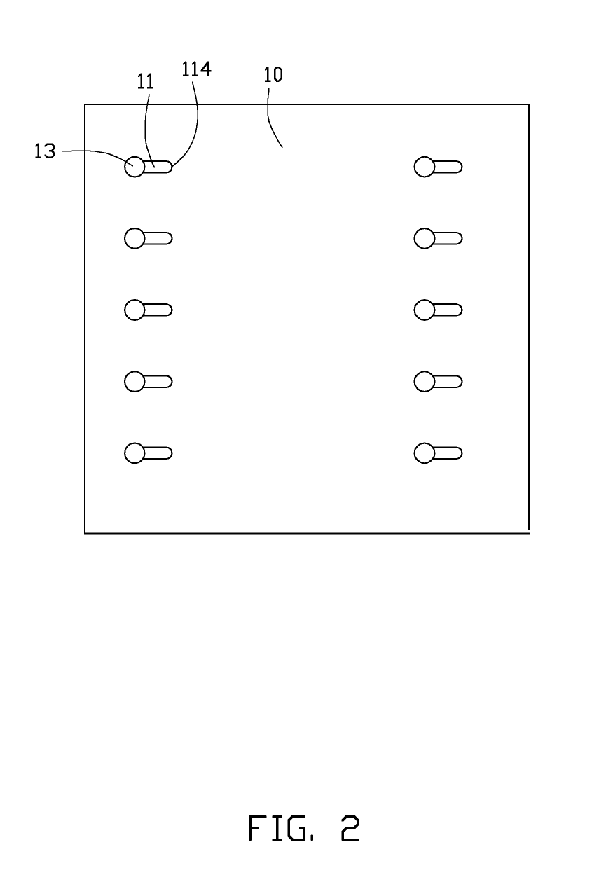

Referring to FIG. 2, the target 10 defines at least one array of openings 11, in this exemplary embodiment there are two arrays of openings 11. Each opening 11 is substantially rectangle with a first end 112 and a second end 114. In this exemplary embodiment, the first end 112 and the second end 114 are both semi-circular. The base 30 defines equal array of threaded holes 31 corresponding to the openings 11. When the first end 112 of each opening 11 is aligned with one of the threaded holes 31, and each screw 13 is inserted into corresponding first end 112 and tightly screwed in corresponding threaded hole 31, so the target 10 is held on the base 30 in a first position shown in FIGS. 1 and 2.

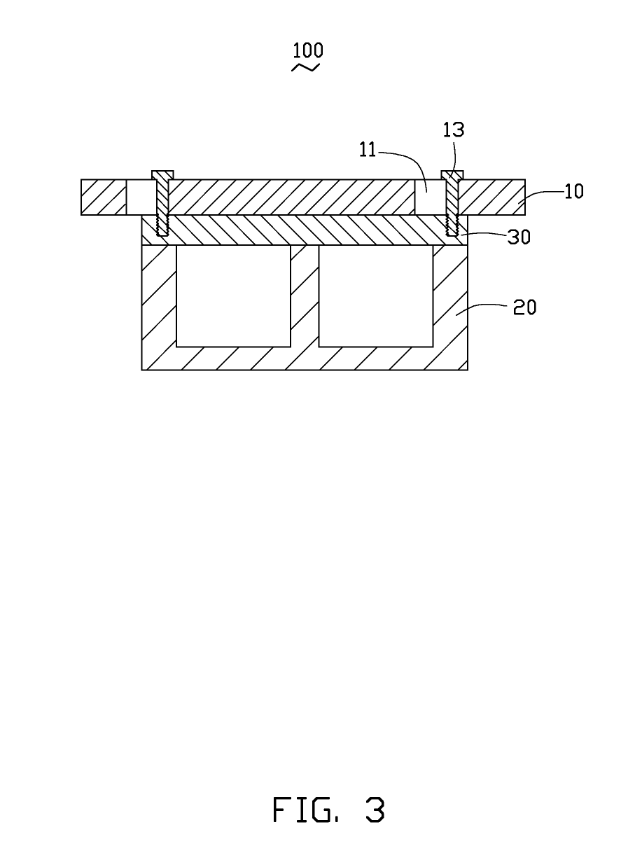

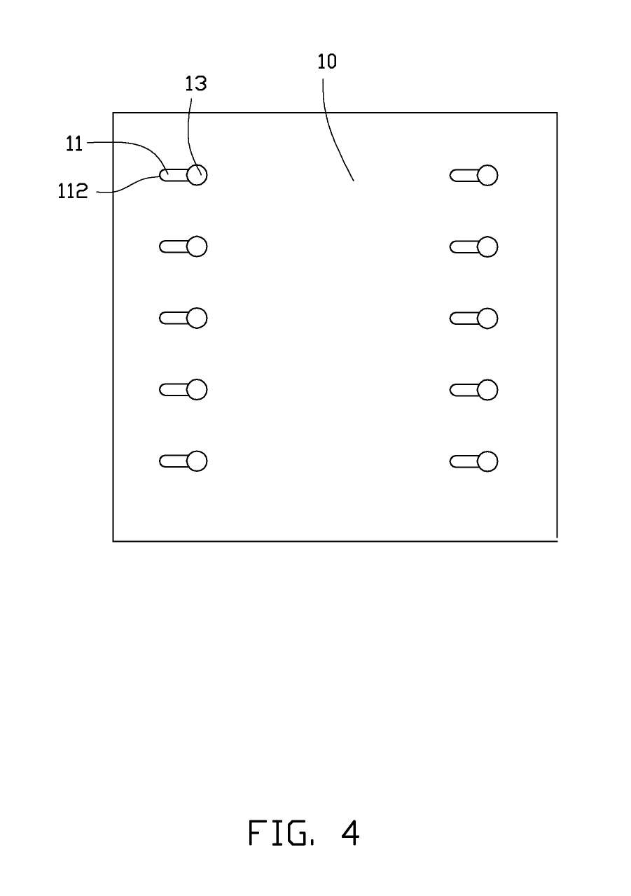

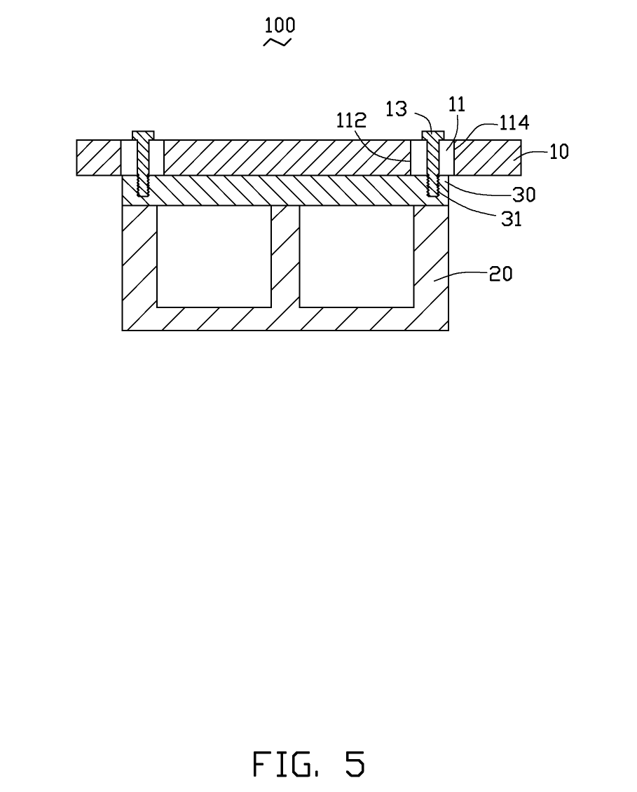

Referring to FIGS. 3 and 4, to adjust the position between the magnetron 20 and the target 10, each screw 13 is loosely screwed from the corresponding threaded hole 31 to release the target 10 from the base 30. Then the target 10 can be moved relative to the base 30 so each screw 13 respectively slides in the corresponding opening 11 toward the corresponding second end 114. Once each screw 13 slides to the corresponding second end 114, each screw 13 is tightly screwed in the corresponding threaded hole 31 and the corresponding second end 114 to hold the target 10 on the base 30 in a second position shown in FIGS. 3 and 4. It is to be understood that each screw 13 can slide to and be tightly screwed anywhere between the corresponding first end 112 and the corresponding second end 114 in the corresponding opening 11, like a third position shown in FIG. 5, to adjust the position between the magnetron 20 and the target 10. Thus, the bombarded area of the target 10 can be adjusted by the adjustment of the screw 13, to increase the utilization rate of the target 10.

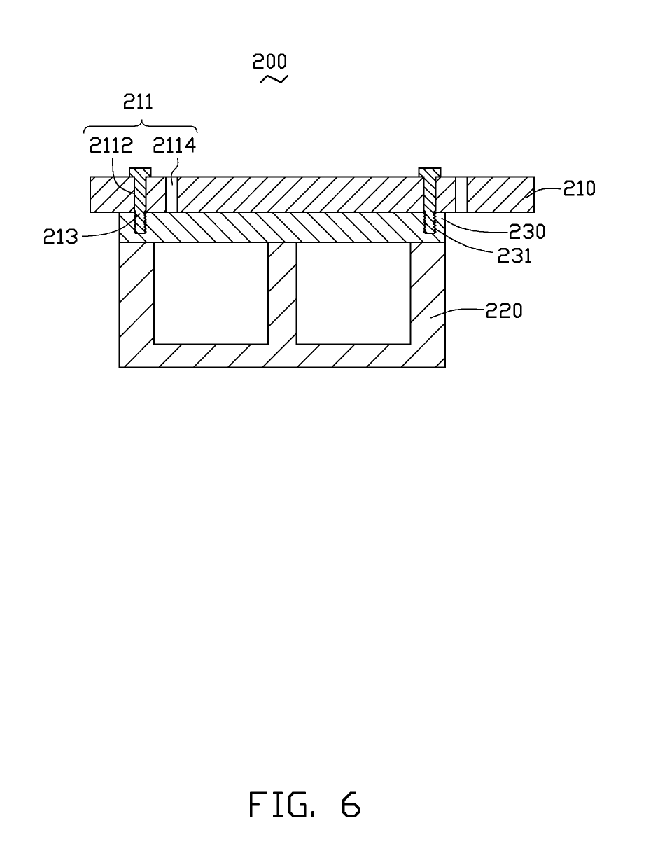

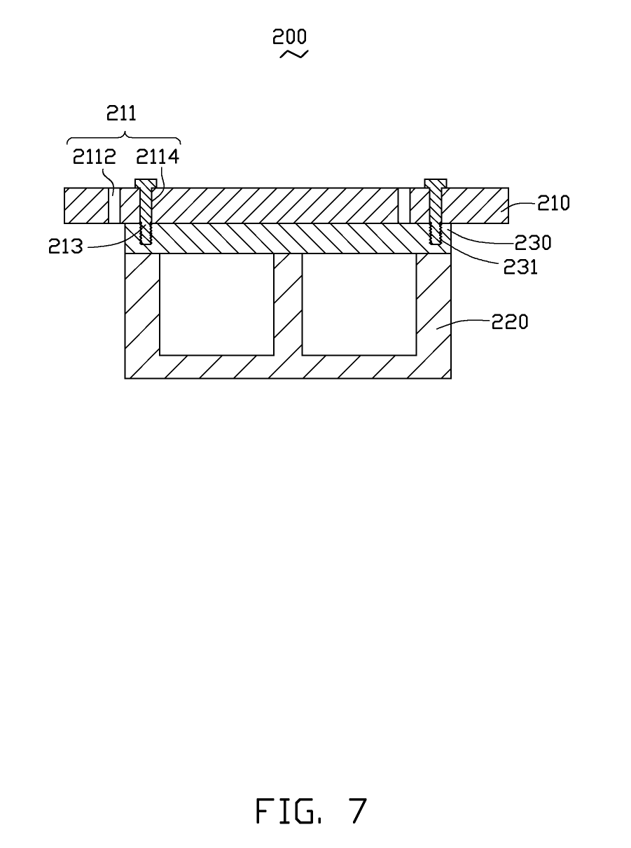

Referring to FIGS. 6 and 7, one alternative embodiment of a target assembly 200 is shown. The target assembly 200 includes a target 210, a magnetron 220, a base 230 and at least one screw 213. The magnetron 220 is mounted on a first surface of the base 230, the target 210 is adjustably positionable relative to a second surface of the base 230 opposite to the magnetron 220 by the screws 213. The target 210 defines at least one group of openings 211, each group includes a first opening 2112 and a second opening 2114 adjacent to the first opening 2112. The base 230 defines at least one threaded hole 231. When each first opening 2112 is aligned with corresponding threaded hole 231, and each screw 213 is inserted into corresponding first opening 2112 and tightly screwed in corresponding threaded hole 231, the target 210 is held on the base 230 in a first position shown in FIG. 6. To adjust the position between the magnetron 220 and the target 210, each screw 213 is loosely screwed to release the target 210 from the base 230, and make each second opening 2112 align with the corresponding threaded hole 231. Each screw 213 is inserted into the corresponding second opening 2112 and tightly screwed in the corresponding threaded hole 231 again so the target 210 is held on the base 230 in a second position shown in FIG. 7. Thus, the bombarded area of the target 210 can be adjusted to increase the utilization rate of the target 210.

It is to be understood, however, that even through numerous characteristics and advantages of the exemplary disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A target assembly, comprising:
a base comprising a first surface and a second surface opposite to the first surface;
a magnetron mounted on the first surface; and
a target being adjustably positionable relative to the second surface to adjust a position between magnetron and the target.

2. The target assembly as claimed in claim 1, wherein the base is made of magnetic material so the magnetron is bonded to the base by the magnetic force therebetween.

3. The target assembly as claimed in claim 1, wherein the target is made of metal, alloy, metal oxide or metal nitride.

4. The target assembly as claimed in claim 1, wherein the target defines at least one array of openings, each opening including a first end and a second end; the base defines equal array of threaded holes corresponding to the openings; the target assembly further comprises a plurality of screws; each screw is capable of being selectively screwed in one of the first end, the second end and a position therebetween in corresponding threaded hole to hold the target on the base in a different position.

5. The target assembly as claimed in claim 4, wherein each opening is substantially ellipse.

6. The target assembly as claimed in claim 4, wherein each screw selectively slide to and be tightly screwed anywhere between corresponding first end and corresponding second end in corresponding opening, to adjust the position between the magnetron and the target.

7. A target assembly, comprising:
a base comprising a first surface and a second surface opposite to the first surface, the base defining a threaded hole;
a magnetron mounted on a first surface; and
a target movably mounted to the second surface, the target defining an opening corresponding to the threaded hole, the opening including a first end and a second end; and
a screw;
wherein the screw can slide in the opening from the first end to the second end so a position between magnetron and the target is adjusted to adjust the bombarded area of the target.

8. The target assembly as claimed in claim 7, wherein the base is made of magnetic material so the magnetron is bonded to the base by the magnetic force therebetween.

9. The target assembly as claimed in claim 7, wherein the target is made of metal, alloy, metal oxide or metal nitride.

10. The target assembly as claimed in claim 7, wherein the opening is substantially rectangular with semi-circular ends.

11. The target assembly as claimed in claim 7, wherein the screw selectively slide to and be tightly screwed anywhere between the first end and the second end in the opening, to adjust the position between the magnetron and the target.

12. A target assembly, comprising:
a base comprising a first surface and a second surface opposite to the first surface, the base defining at least one threaded hole;
a magnetron mounted on a first surface;
a target is movably mounted to the second surface, the target defining at least one group of opening, and each group including a first opening and a second opening adjacent to the first opening; and
at least one screw;
wherein when each first opening is aligned with corresponding threaded hole, and each screw is inserted into corresponding first opening and tightly screwed in corresponding threaded hole, the target is held on the base in a first position;
when each second opening is aligned with corresponding threaded hole, and each screw is inserted into corresponding second opening and tightly screwed in corresponding threaded hole, the target is held on the base in a second position.

13. The target assembly as claimed in claim 12, wherein the base is made of magnetic material so the magnetron is bonded to the base by the magnetic force therebetween.

14. The target assembly as claimed in claim 12, wherein the target is made of metal, alloy, metal oxide or metal nitride.
